(19) United States
(12) Patent Application Publication
(10) Pub. No.: US 2026/0169034 A1
(43) Pub. Date: Jun. 18, 2026

(54) DETERMINATION OF AN ELECTRIC ENERGY FLOW

(71) Applicant: Siemens Aktiengesellschaft, 80333 München (DE)

(72) Inventors: ANDREAS GRÖGER, München (DE); KAI KRIEGEL, München (DE); OLIVER RAAB, 94496 Ortenburg (DE); HANS SANTOS WILKE, Parsdorf (DE)

(73) Assignee: Siemens Aktiengesellschaft, 80333 München (DE)

(21) Appl. No.: 19/126,833

(22) PCT Filed: Oct. 31, 2023
(86) PCT No.: PCT/EP2023/080357

§ 371 Date: May 2, 2025

(30) Foreign Application Priority Data
Nov. 4, 2022 (EP) 22205599.8
Apr. 26, 2023 (EP) 23169950.5

(51) Int. Cl. G01R 15/14; G01R 15/20; G01R 21/06

(52) U.S. Cl. CPC G01R 15/142; G01R 15/202; G01R 15/205; G01R 21/06

(57) ABSTRACT

A method and a device determine an electric flow in an electric conductor by a non-contact current measurement apparatus and a non-contact voltage measurement apparatus, as well as a measurement signal processing apparatus which is designed to determine an electric power and/or energy from measured current values and voltage values. At least one of the non-contact measurement apparatuses has an electromagnetic field shielding. By spacers, the device is arranged in a galvanically separated manner on an electric conductor to be measured.

The invention relates to a method for determining an electric power and/or energy flow through an electric conductor in which the two physical variables “current and voltage” are determined simultaneously at one location and the electric power and/or electric energy is ascertained therefrom. Furthermore, the invention relates to a device for determining an electric power and/or energy flow.

### PRIOR ART

The exact determination of electric energy flows and energy consumption is an important task in various fields of application, such as industrial automation, building technology and also in large-scale electricity distribution networks. In particular in the course of the ongoing transition to renewable energy and decentralization of energy generation, in future, the ability to map electric energy flows will be of crucial importance.

To determine electric energy flows, it is necessary to simultaneously measure the two physical variables “current and voltage” at the same location, i.e. on the same line section. Different measurement methods are available for performing current and voltage measurements. Up to now, energy measurements have preferably been performed using a device that is inserted into an existing power connection, for example an electric line or a power cable.

This is necessary because at present proven voltage measurements are in most cases performed by means of contact methods, for example using an analog-to-digital converter. Contact methods require physical contact to be established with the measurement object in order to perform a direct measurement in the circuit. For this purpose, therefore, it is necessary to use a permanently integrated measuring device or alternatively, the isolation of the power line to be measured would have to be interrupted, i.e. damaged. In particular with existing systems (“brownfield”), this necessary direct physical contact with the current-carrying line has the disadvantage that they have to be temporarily disconnected from the mains to perform a measurement or for installation and that strict safety requirements have to be met in terms of electrical safety during subsequent operation. Galvanic isolation is also necessary for data transmission.

Although non-contact methods, such as Hall sensors or Rogowski coils, are also available for measuring a current flow, a combination of current and voltage measurements to determine electric power or energy always presents the challenge of contact voltage measurement.

A method for non-contact voltage measurement is known from the prior art, for example DE 10 2010 035 381 A1 and DE 10 2008 052 477 A1: the principle of the MEMS voltmeter, also referred to as a micromechanical field mill, is based on measuring the change over time of electric capacitance by means of a microelectromechanical system. The change in capacitance over time is induced mechanically using an electric, electrostatic or thermal actuator. In order to measure the change in capacitance, a displacement current is captured by a current-voltage converter and a measurement signal is generated as a result. The influence of the electric voltage to be measured on the measurement result is eliminated by the fact that the voltage contains constant components and the current-to-voltage converter is scanned during the switching edges of the voltage. This enables an impulse response to voltage changes in the voltage to be measured, which also affect the measuring capacitor, to be masked out. Use is made of the property of the capacitive measuring principle that a signal can only be detected if charges are displaced on the capacitor and initiate a displacement current I(t). The applicable equation for this is I(t)=dC/dt·U+dU/dt·C, wherein C is the capacitance of the capacitor and U is the voltage applied to the capacitor. The capacitance of the capacitor, or the capacitance between a measurement object, for example a current-carrying conductor, and the sensor, i.e. the MEMS voltmeter, can be changed by changing the area of the capacitor plates, in particular by inserting apertures into the capacitor gap, by changing the distance between the capacitor plates or by changing the relative dielectric constant of the medium between the plates, according to DE 10 2010 035 381 A1 and DE 10 2008 052 477 A1.

Based on the above-described prior art, the invention is based on the object of providing a method and a device for non-contact determination of an electric power and/or energy flow.

This object is achieved by the features of independent claim 1 and by the features of independent claim 5. Advantageous embodiments of the invention are the subject matter of the subclaims.

The method according to the invention for non-contact electric power and/or energy determination comprises a measurement signal processing step in which the electric power and/or energy is ascertained from measured current and voltage values. Herein, first, a device according to the invention with an electric conductor to be measured is arranged in a galvanically isolated manner, a current measurement is performed on the electric conductor by determining the magnetic field emanating from the current-carrying conductor by means of a first sensor, at the same time, a voltage measurement is performed on the electric conductor by determining the electric field emanating from the current-carrying conductor by means of a second sensor, and these two measurement signals are offset against one another either in an analog manner by means of an electric circuit and/or in a digital data processing step. The term “in a galvanically isolated manner” should be understood as meaning that, that although there is a potential effect as an electric field and magnetic field due to the current flow, there is electrical isolation, so that no current flows between the conductor to be measured and the device. Herein, the arrangement is expediently achieved by means of spacers, e.g. via a mechanical mounting device or via metrologically defined positioning, in particular also without a structural connection to the conductor to be measured. A key advantage of this is that existing systems, e.g. brownfield systems, can be retrofitted without structural intervention.

Preferably, in the method according to the invention for non-contact electric power and/or energy determination, the voltage measurement is carried out by means of a MEMS voltmeter.

In a particularly advantageous variant of the method, the device is arranged in a galvanically isolated manner by means of spacers at a predeterminable measuring distance relative to the electric conductor to be measured. This in particular allows a minimum distance of 100 μm and a maximum distance, to be set in relation to the voltage levels to be determined and further sources of interference. For this purpose, spacers are provided, which are in particular also embodied as a mounting device, cable guide, cable clamp or, particularly advantageously, already comprise parts of the current sensor, in particular the magnetic field concentrators. Alternatively, the spacers comprise distance sensors, thereby enabling the measurement distance to be fixed.

A further variant of the method comprises at least one analog measurement signal preprocessing step at the level of the sensors in which the output of an analog signal is in particular generated by means of I/U converters, high-pass filters, low-pass filters and/or amplifiers.

The method according to the invention is particularly advantageous because it enables electric power and/or energy to be determined with high temporal resolution. In particular, the measurements are carried out at a sampling rate that is at least one order of magnitude higher than the frequency of the measurement signal. Simultaneous measurement of the two physical variables “current and voltage” means that the power or energy value is also determined on board and simultaneously.

The device according to the invention comprises a non-contact current measurement apparatus and a non-contact voltage measurement apparatus, wherein at least one of the non-contact measurement apparatuses has electromagnetic field shielding, with a measurement signal processing apparatus, which is embodied to ascertain an electric power P=u·l and/or energy E=ƒu·i dt from the measured current and voltage values, and wherein it comprises at least one spacer, in particular a mounting device, by means of which the device can be arranged on an electric conductor to be measured in a galvanically isolated manner therefrom. The proposed solution combines two non-contact measurement methods. A key advantage of this device is that it enables precise, high-resolution and simultaneous determination of the two physical variables “current and voltage” to be performed at the same measuring point or measuring section of an electric conductor to be measured and an electric power or electric energy to be ascertained therefrom. This presents an electrical arrangement that solves the twin problems of mains Isolation and safety requirements using a non-contact method.

Non-contact measurement should be understood to be indirect measurement that measures an electric voltage or an electric current without contact, i.e. without potential. A live measurement object generates an electric field. This electric field can be measured without contact, based on a measurement of the change in electric capacitance over time. Non-contact current measurement uses the magnetic field induced by moving charges as the physical measured variable. The instantaneous power P=u·i in the current-carrying conductor or the temporally integrated energy flow E=ƒu·i dt in the current-carrying conductor is determined with the aid of a computer operation. In non-contact measurement, there is no electrical contact and no intervention in a circuit, which means the insulation remains undamaged due to the presence of galvanic isolation. The spacers also enable existing systems, e.g. so-called brownfield systems, to be very easily retrofitted without intervention and thus also easily digitized.

In a particularly preferred embodiment of the invention, the non-contact voltage measurement apparatus comprises a sensor for measuring an electric field strength. In particular, the voltage measurement apparatus is embodied as a MEMS voltmeter. A key advantage of this is that MEMS voltmeter technology can cover very wide voltage measurement ranges—from a few volts up to several kilovolts.

The principle of the MEMS voltmeter is based on the periodic shielding of two electrodes in an external electric field. With constant capacitance of the electrodes and constant distance to an external potential, the voltage can be calculated. Bahrenyni et al., Analysis and Design of a Micromachined Electric-Field Sensor, Journal of Microelectromechanical Systems, Vol. 17, No. 1, February 2008, pp. 31-36 describes, for example, that electric-field meters are common sensors for electric fields in the aforementioned fields of application. The principle of operation is based on a grounded shutter that repeatedly shields a sensor electrode arrangement from a field to be measured and exposes it to the field again. According to Gauss's law, the sensor electrode arrangement is alternately discharged and charged behind the shutter by the influence of the external electric field (displacement current). In the present case, a miniaturized device is proposed for this purpose.

In a further preferred embodiment of the invention, the device comprises a current measurement apparatus and a voltage measurement apparatus, which are arranged in two separate chip packages on a common circuit carrier. In an alternative, equally advantageous, embodiment of the invention, the device comprises a current measurement apparatus and a voltage measurement apparatus, which are arranged on two separate sensor chips within a common chip package. In a further alternative, equally advantageous, embodiment of the invention, the device comprises a current measurement apparatus and a voltage measurement apparatus, which are arranged on a common sensor chip, in particular as integrated electronics. Herein, a circuit carrier should, for example, be understood to be a printed circuit board or an alternative base for an electronic assembly. A sensor chip should in particular be understood to be a semiconductor substrate, a so-called die or wafer, which, in contrast to the chip package, is still unhoused, i.e. bare. Accordingly, the chip package should be understood to be an encased semiconductor chip, wherein, herein, the chip housing can take on protective, mounting and spacer functions.

In all cases, both measurements-current and voltage measurement—are measured from one board. Preferably, both measurement apparatuses are located a few centimeters apart, which is understood to mean “the same location”, “same measuring point” or “measurement on the same line section”. The ability to perform current and voltage measurements at the same location in this way can in particular be enabled by the fact that the electromagnetic field shielding means there are no field interferences that could interfere with the measurement. Preferably, the measurements are also evaluated on the same board. Alternatively, several boards or circuit carriers are stacked.

In an advantageous variant of the device, the non-contact current measurement apparatus comprises a Hall element. A Hall sensor can measure direct and alternating currents. A Hall element is based on the measurement of magnetic flux density. Even with a very small current of around 0.5 A and a simple silicon-based Hall sensor, it is possible to achieve a measurable Hall voltage of 10 mV. Usually, a Hall element comprises magnetic flux concentrators made of iron, so-called IMCs. The measurement can also be carried out using so-called XMR sensors in which there is a change in electrical resistance due to the magnetic flux. XMR sensors are sensors for magnetic flux densities, in particular thin-film sensors, which change their resistance directly under the influence of the magnetic flux. These include, for example GMR sensors, AMR sensors or CMR sensors.

One alternative is the Rogowski coil for non-contact current measurement. However, the Rogowski coil can only measure alternating voltage. A Hall element does not have this restriction.

In a further advantageous variant of the device, the measurement signal processing apparatus is embodied to offset the two measurement signals, i.e. current and voltage, against one another in an analog and/or digital manner. If the current and voltage are known, the values for power P=U*I and energy E=ƒP dt are simple computing operations. Digital evaluation has the advantage that the individual values are then also available in digital form.

A further advantageous variant of the device comprises a signal preprocessing apparatus at the level of the sensors, in particular one of the two measuring devices, e.g. I/U converters, high-pass filters, low-pass filters and/or amplifiers, which outputs an analog signal to the measurement signal processing apparatus.

Preferably, the device or the measurement signal processing apparatus comprises a further signal processing apparatus on a common circuit carrier or a common circuit carrier stack. In particular, the device or the measurement signal processing apparatus is embodied to communicate at system level by means of the common circuit carrier. For example, the device has a connection for data output, a plug, data connection system or another interface, which is in particular used to communicate with a data processing device, for example a computer. Computers can, for example, be understood to mean personal computers, servers, handheld computer systems, pocket PC devices, cell phone devices, edge devices and other communication devices, which can process data in a computer-aided manner, processors and other electronic devices for data processing.

Expediently, the device, or the measurement signal processing apparatus has a BUS system for combining the measurement signals, in particular for determining digital power and/or energy values. Alternatively, the measurement signal processing apparatus has evaluation electronics for analog evaluation . . .

### DESCRIPTION OF THE FIGURES

Further features, properties and advantages of the present invention emerge from the following description with reference to the accompanying FIGS. 1 to 13. It is shown in:

FIG. 1 a schematic view of the mode of operation of the MEMS voltmeter.

FIG. 2 a schematic view of the measuring principle of the energy meter.

FIG. 3 measurement results from the MEMS voltmeter.

FIG. 4 a simulation of a current-carrying conductor and a Hall element.

FIG. 5 a schematic design drawing of the MEMS voltmeter.

FIG. 6 a schematic view of the measuring principle of the energy meter with electromagnetic field shielding.

FIG. 7 a schematic view of the structure of the energy meter arranged with a cable.

FIG. 8 a schematic view of a cross section through the housing of the energy meter.

FIG. 9 a schematic view of the IMC of the Hall element as a cable clamp.

FIG. 10 a schematic view of the measuring principle of the Hall element.

FIG. 11 a schematic view of the cross section through the housing of the energy meter as shown in FIG. 9.

FIG. 12 a schematic view of an isolating spacer embodied as a cable bushing.

FIG. 13 a circuit drawing of an analog signal (pre) processing apparatus.

FIG. 14 a schematic view of a spacer with distance sensors.

In the exemplary embodiments and figures, elements that are identical or have an identical effect can in each case be provided with the same reference symbols. The elements depicted and their relative sizes are generally not to be considered to be true to scale; rather individual elements may be shown proportionally larger for better visualization and/or for better clarity.

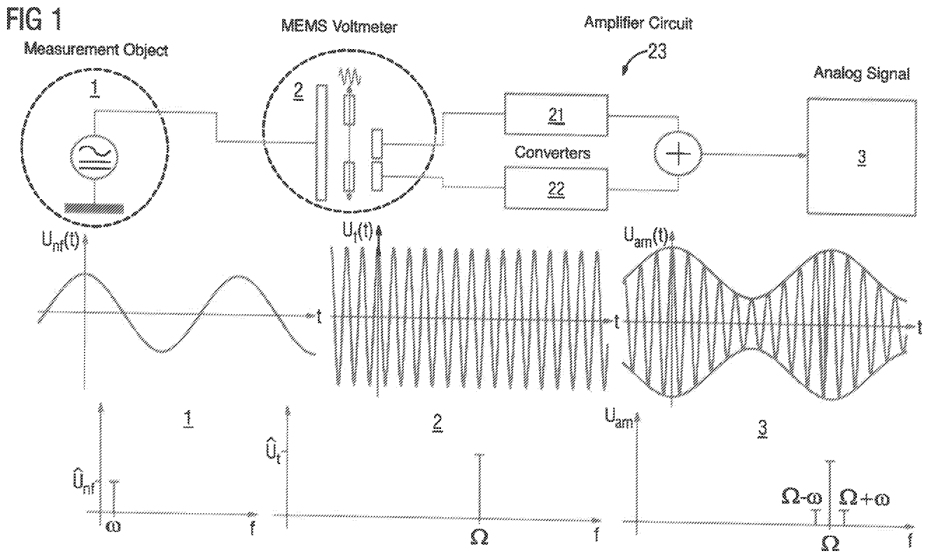

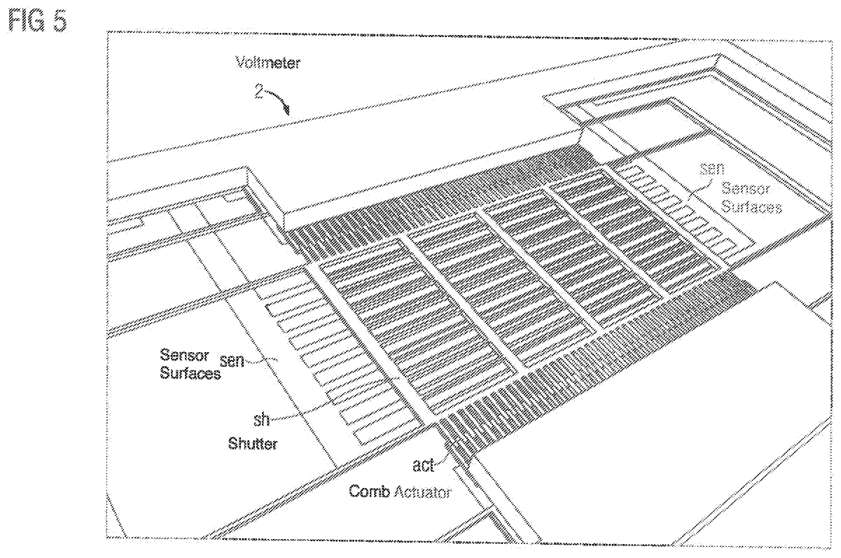

FIG. 1 is a schematic view of the mode of operation of the MEMS voltmeter 2: a live U measurement object 1 generates an electric field E. This electric field E in measured in a non-contact manner with the aid of the MEMS voltmeter 2. FIG. 5 shows a schematic design drawing of the MEMS voltmeter 2. It comprises two capacitor plates sen which are electrically isolated from one another and interconnected via an amplifier circuit 23, see FIG. 13. An oscillating electrode sh, which is at a neutral reference potential, is arranged spatially plane-parallel above these capacitor plates sen, or along the direction of the source of the electric field E to be measured. Depending on the deflection, this oscillating electrode sh shades one of the two capacitor plates sen from the electric field E of the external electric conductor con to be measured. A current flows relative to the strength of the external electric field E during each oscillation passage of the electrode sh. Herein, the preliminary signs of the currents of the two capacitor plates are always opposite. The difference between these current flows is proportional to the electric field E of the conductor con and can be measured by the amplifier circuit 23. This electric field E is in turn defined by the electric voltage U of the conductor con and the distance to the conductor con.

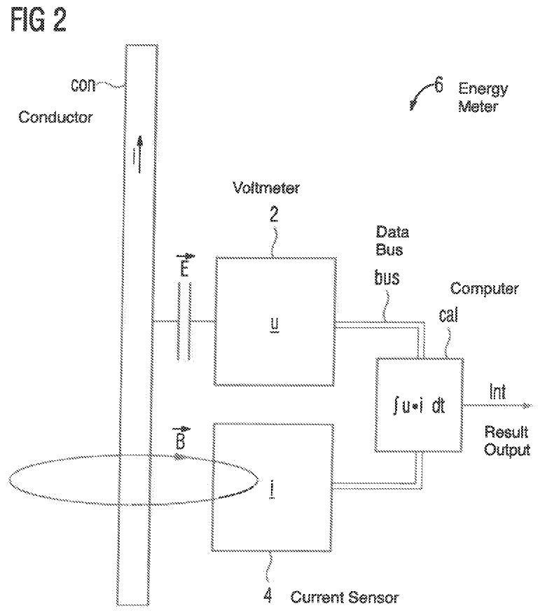

If this voltage measurement 2 is combined with a non-contact current measurement 4, e.g. based on a magnetic field sensor, in particular a Hall sensor or a Rogowski coil, the instantaneous power P in the conductor con or the temporally integrated energy flow in the conductor con can be determined with the aid of a simple computer operation cal. The current measurement 4 uses the magnetic field B generated by moving charges as a physical measured variable. The measuring principle of such an energy meter 6 is shown in FIG. 2: determining the current and voltage flows at the same time enables the current power flow u·i in the conductor to be calculated by a simple multiplication of the two values con or the energy flow ƒu·i dt through the conductor con to be calculated by temporal integration.

The two sensors 2, 4 can be arranged in different ways. For example, the voltmeter 2 and the current sensor 4 can be accommodated monolithically on a single semiconductor substrate. In a further embodiment, two sensor chips 2, 4 are accommodated within a common chip package. In a third embodiment, two independent chip packages are connected on a common circuit carrier boa.

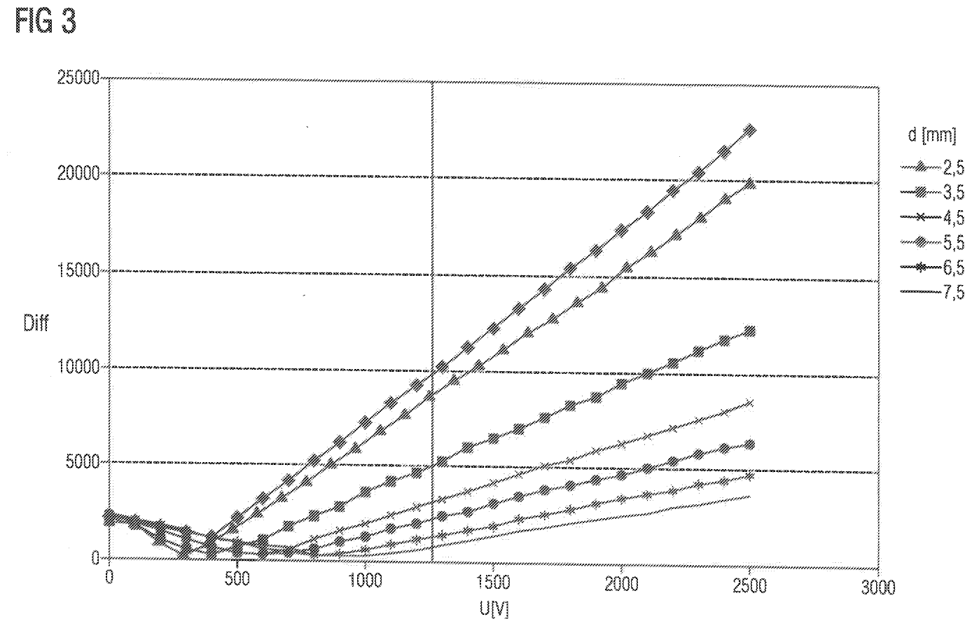

FIG. 3 shows measurement results from the MEMS voltmeter, the amplitude difference Diff=Max−Min in ADC digits, in dependence on the measured voltage U in volts and distance d in mm between the sensor 2 and the power line con. The measured values show a linearity regardless of the measuring distance d. A good response of the sensor 2 at different voltages U and distances d between the sensor and the measuring line con is shown,

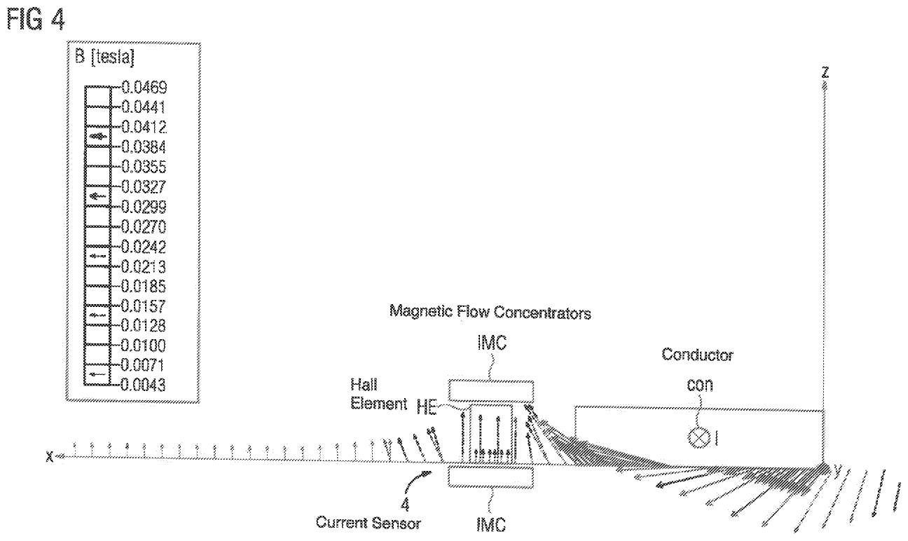

FIG. 4 shows a simulation of a current-carrying conductor con and a Hall element HE with magnetic flow concentrators IMC made of iron. The arrows show the magnetic field strength or magnetic flux density B in tesla in the three spatial directions x, y, z. For comparison: the earth's magnetic field in central European latitudes has a magnetic flux density B of 48 μT. In one embodiment of the device according to the invention, for example an energy meter 6, the MEMS voltmeter 2 is coupled to a Hall sensor 4. The two measurement signals i, u are offset against one another in an analog and/or digital manner cal.

With regard to the MEMS voltmeter component 2, FIG. 5 shows a schematic design drawing of a MEMS chip 2. Such a MEMS chip can, for example, be used to achieve measurement results as shown in FIG. 3.

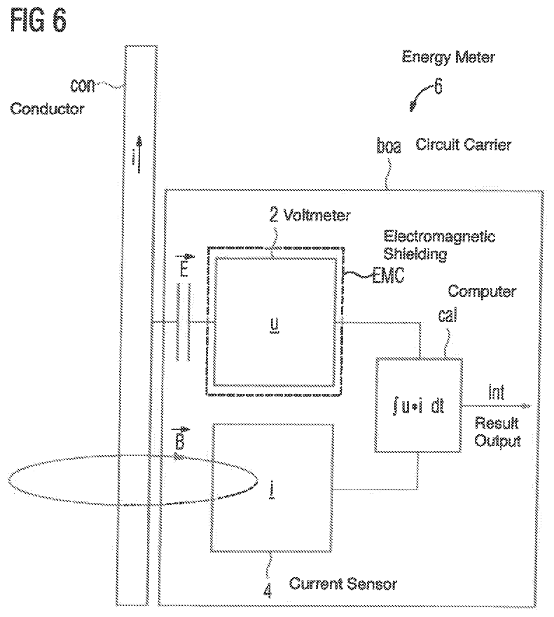

FIG. 6 is a schematic view of the measuring principle of the energy meter 6 with electromagnetic field shielding EMC of the voltage measuring device 2. Alternatively or additionally, the current measuring device 4 can also be surrounded by electromagnetic field shielding EMC. Alternatively or additionally, in one embodiment of the energy meter 6, the entire unit comprising measuring devices 2, 4 and evaluation unit 23 cal has electromagnetic field shielding EMC.

Accordingly, the evaluation electronics 23 cal can be integrated at different levels. For example, certain preprocessing 23 of the signals can be performed at the level of the sensors 2, 4, but final processing can be performed on the common circuit carrier boa. Communication then also takes place with the aid of this circuit carrier boa.

In an alternative embodiment of the device 6, it is also possible to capture the two measured variables u, i with a certain spatial separation, but on the same conductor. The measurement signals are then, for example, combined via a bus system bus, as shown in FIG. 2. The subsequent processing cal then takes place, for example, by means of connected evaluation electronics or a digital evaluation apparatus, e.g. a microprocessor.

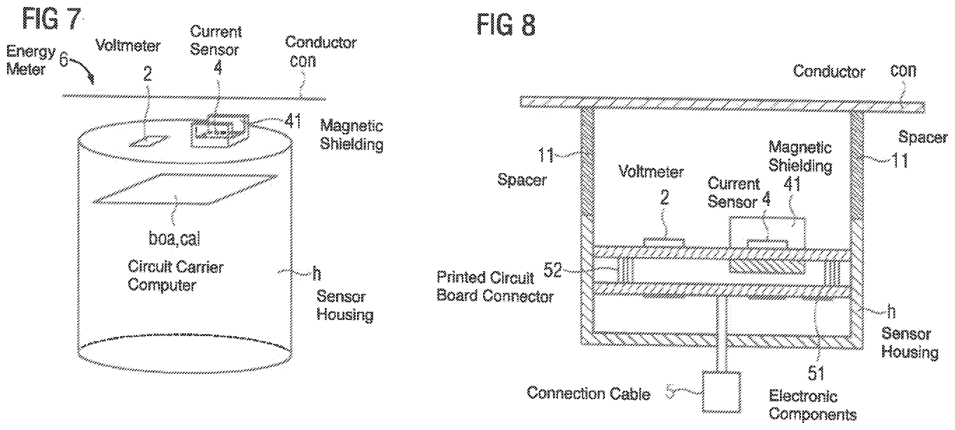

FIG. 7 is a schematic view of the structure of the energy meter 6 with a sensor housing h and internal electronics boa cal, arranged with a cable con. FIG. 8 is a schematic view of the cross section through the housing h of the energy meter 6. This shows a circuit carrier stack consisting of several boards boa, which are connected via printed circuit board connectors 52. Furthermore, a connection cable or plug 5 is provided. Further electronic components 51 can be provided on the printed circuit boards boa. The current measurement apparatus 4 has magnetic shielding 41. This in particular comprises magnetic flux concentrators made of iron, so-called IMCs. However, herein, the u-shaped flux concentrator is arranged rotated by 90° to the conductor con.

Furthermore, the energy meter-device 6 has, for example, isolating spacers 11, which in particular are also used for locking on the conductor con to be measured. On the one hand, the spacers 11 achieve the galvanically isolated arrangement and, on the other, enable a distance d between the sensors 2, 4 and field source con to be set.

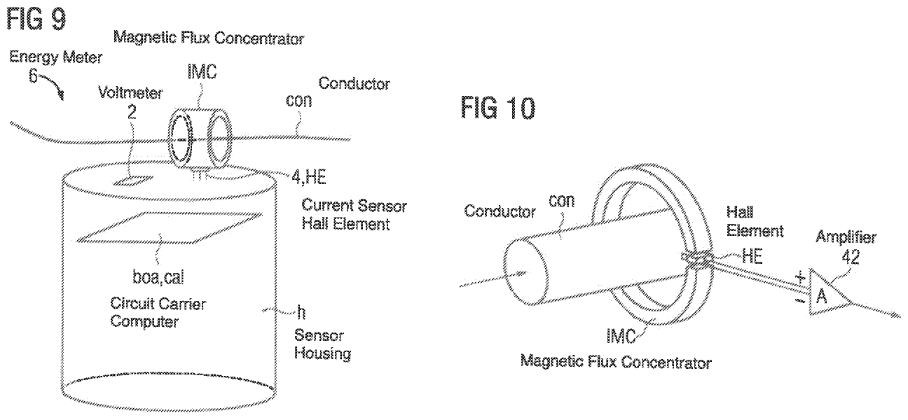

FIG. 9 is a schematic view of the flux concentrator IMC of the Hall element HE as a type of cable clamp. The associated measuring principle of the Hall element HE is shown schematically in FIG. 10. The analog measurement signal is, for example, output via an amplifier 42. Such an amplifier 42 can, for example, represent an analog measurement signal preprocessing apparatus or be contained therein.

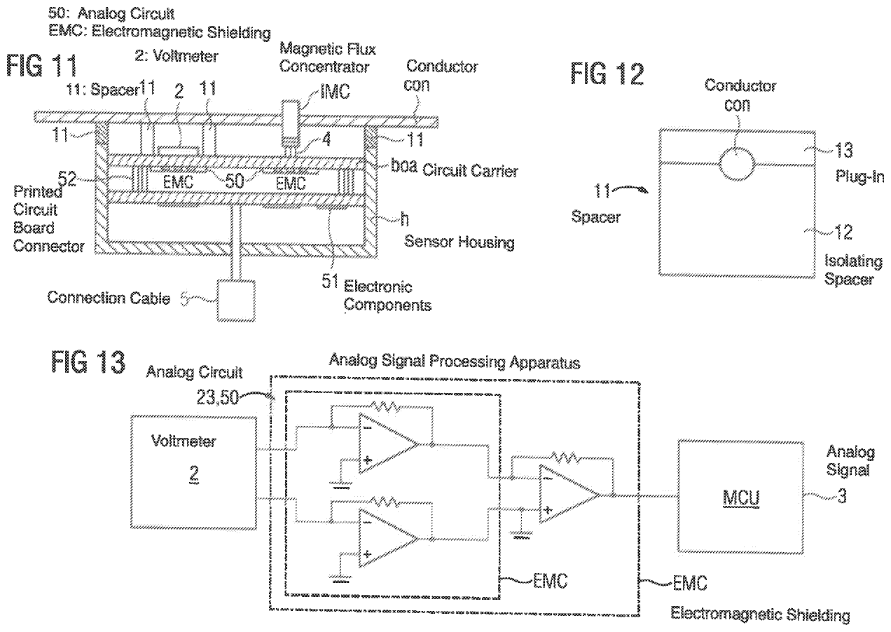

FIG. 11 is a schematic view of the cross section through the housing h of the energy meter 6 as shown in FIG. 9. This again shows a circuit carrier stack consisting of a plurality of boards boa, which are connected via printed circuit board connectors 52. Furthermore, a connection cable or plug 5 is provided. Analog circuits in each case with EMC shielding 50 are provided on the printed circuit boards boa. These can, for example, be the analog measurement signal preprocessing apparatuses of the current and voltage measuring device in each case. The current measurement apparatus 4 has a circular flux concentrator IMC arranged around the cable con to be measured. The voltage sensor 2 has electromagnetic shielding EMC, which in particular also shields the two sensors 2, 4 from one another. The shielding EMC, 50 of the evaluation electronics is particularly important for the voltage sensor 2. However, the actual sensor 2 must remain exposed to the conductor con. It is advantageous if these evaluation electronics are located on the side of the board boa facing away from the conductor con to be measured, as also shown in FIG. 11.

FIG. 12 is a schematic view of a possible embodiment of an isolating spacer 11 embodied as a cable bushing. This spacer 11 comprises an isolating spacer as a lower part 12 and attachment to the energy meter device 6 and a plug-in or clip-on upper part 1, by means of which the cable con to be measured can be fixed. This cable bushing accordingly ensures a galvanically isolated arrangement.

Particular attention should also be paid to the influence of interference fields on the measurement. If, for example, measurements are to be taken in a multiphase system, care must be taken to ensure that the phases that are not to be measured are shielded by suitable conductive shielding EMC and/or the distance d between the sensor 2 and the conductor con to be measured is substantially smaller than the distance d between the conductor con and an interfering field, e.g. caused by a further conductor. Therefore, the device 6 is preferably also embodied in such a way that supply lines, such as measuring lines and/or supply lines of the sensor 2, are shielded from external electric fields in order to avoid interference coupling. In addition, the arrangement of the supply lines, e.g. for radio-frequency excitation of the oscillating electrode sh, and the measuring lines must be suitably selected in order to avoid crosstalk of the radio-frequency excitation into the sensitive measuring channels.

FIG. 13 shows a circuit drawing of an analog signal (pre) processing apparatus 23, 50. This circuit diagram shows in highly simplified form how the voltmeter parts can be shielded. For example, parts of the analog circuit 23, 50 are shielded in order to amplify both sensor paths or even further including the differential amplifier that outputs the analog signal 3. As shown in FIG. 5, the actual MEMS component, is, for example, arranged on the rear of the shielding EMC or the PCB, see cross section in FIG. 11. The Hall sensor could additionally be shielded in a comparable way. However, preferably, at least the voltmeter is shielded.

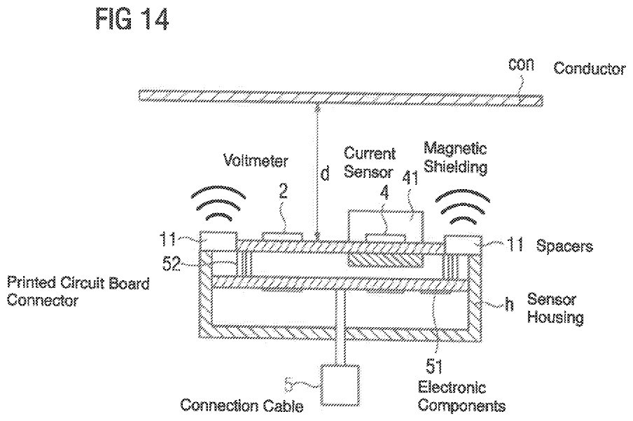

FIG. 14 is a schematic view of spacers 11 with distance sensors. These are particularly advantageous when used to measure overhead lines and underground cables since no structural connection to the conductor con to be measured is required. If the distance is precisely known, it would also be possible to work without sensors.

Although the invention has been illustrated and described in detail by the preferred exemplary embodiments, the invention is not restricted by the disclosed examples. Variations can be derived herefrom by the person skilled in the art without departing from the scope of protection of the invention as defined by the following claims.

List of reference symbols

| | |
|---|---|
| 1 | Measuring voltage |
| 2 | MEMS voltmeter, measuring device |
| sen | Sensor surfaces |
| sh | Shutter, movable |
| act | Comb actuator |
| 21 | I/U converter |
| 22 | I/U converter |
| 3 | Analog signal, signal output of the voltage sensor |
| 4 | Current sensor, e.g. Hall element HE |
| bus | Data bus |
| cal | Computer, evaluation unit |
| Int | Result output: e.g. energy flow |
| h | Sensor housing with internal electronics (boa cal) |
| 5 | Connection cable, plug |
| 51 | Further electronic components |
| 52 | Printed circuit board connector |
| 41 | Magnetic shielding, flux concentrator (IMC) |
| | (rotated 90° to the conductor con) |
| 11 | Spacer |
| 12 | Isolating spacer embodied as a cable bushing |
| 13 | Plug-in or clip-on upper part |
| Unf(t) | Modulating useful signal |
| Ut(t) | Unmodulated carrier |
| Uam(t) | Modulated carrier |
| U | Voltage |
| t | Time |
| f | Frequency |
| ω | Low frequency |
| Ω | Carrier frequency |
| con | Electric conductor, e.g. cable |
| i | Electric current flow with directional arrow |
| I | Electric current |
| E | Electric field strength |
| B | Magnetic flux density of the magnetic field, induced |
| [tesla] | by electric current flow i |
| d [mm] | Distance voltage to sensor LP |
| Diff | SENSE diff amplitude [max-min] in ADC digits |
| x, y, z | Spatial directions |
| HE | Hall element |
| IMC | Magnetic flux concentrators, e.g. IMCs made of iron |
| boa | circuit carrier, e.g. printed circuit board |
| 42 | Amplifier |
| 50 | Analog Circuit with EMC shielding |
| 23 | Analog signal(pre)processing apparatus |
| EMC | Electromagnetic shielding |

What is claimed is:

1.-15. (canceled)

16. A method for non-contact electric power and/or energy determination in which electric power and/or energy is ascertained from measured current and voltage values in a measurement signal processing step, the method comprising:
arranging a device and an electric current-carrying conductor to be measured in a galvanically isolated manner;
performing a current measurement on the electric current-carrying conductor by determining a magnetic field emanating from the electric current-carrying conductor by a first sensor;
performing a voltage measurement on the electric current-carrying conductor by a MEMS voltmeter by determining an electric field emanating from the electric current-carrying conductor by a second sensor, by a sensor electrode arrangement being repeatedly shielded from the electric field to be measured and exposed to the electric field again by a grounded shutter, so that the sensor electrode arrangement behind the grounded shutter is alternately discharged and charged by an influence of the electric field to be measured; and
offsetting two measurement signals against one another by an electric circuit and/or in a digital data processing step.

17. The method of claim 16, wherein the device is arranged in a galvanically isolated manner by spacers at a predeterminable measuring distance relative to the electric current-carrying conductor to be measured.

18. The method of claim 16, further comprising at least one analog measurement signal preprocessing step at a level of the first and second sensors, in particular by I/U converters, high-pass filters, low-pass filters and/or amplifiers and outputting an analog signal.

19. A device, comprising:
a non-contact current measurement apparatus;
a non-contact voltage measurement apparatus comprising a sensor for measuring an electric field strength, a sensor electrode arrangement and a grounded shutter, wherein the grounded shutter is embodied to repeatedly shield the sensor electrode arrangement from the electric field to be measured and to expose it to the electric field again, in particular the sensor electrode arrangement comprises two capacitor plates which are electrically Isolated from one another and which are interconnected by an amplifier circuit, and in particular an oscillating electrode is arranged spatially plane-parallel above these capacitor plates as a shutter, preferably along the direction of the source of the electric field to be measured, which is at a neutral reference potential and which, depending on a deflection, shields one of the two capacitor plates from the electric field to be measured, in particular embodied as a MEMS voltmeter,
wherein at least one of the non-contact current measurement apparatus and the non-contact voltage measurement apparatus includes electromagnetic field shielding with a measurement signal processing apparatus which is embodied to ascertain an electric power and/or energy from measured current and voltage values, and wherein it comprises at least one spacer by which the device can be arranged on an electric conductor to be measured in a galvanically isolated manner therefrom.

20. The device of claim 19, wherein the non-contact current measurement apparatus and the non-contact voltage measurement apparatus are arranged in two separate chip packages on a common circuit carrier.

21. The device of claim 19, wherein the non-contact current measurement apparatus and non-contact voltage measurement apparatus are arranged on two separate sensor chips within a common chip package.

22. The device of claim 19, wherein the non-contact current measurement apparatus and the non-contact voltage measurement apparatus are arranged on a common sensor chip.

23. The device of claim 19, wherein the non-contact current measurement apparatus comprises a Hall element or an XMR sensor.

24. The device of claim 19, wherein the measurement signal processing apparatus is embodied to offset two measurement signals against one another in an analog and/or digital manner.

25. The device of claim 19, further comprising a signal preprocessing apparatus at a level of the non-contact current measurement apparatus and the non-contact voltage measurement apparatus, the signal preprocessing apparatus is in particular embodied as an amplifier circuit, for measuring a difference in current flows which discharge and charge the capacitor plates during each oscillation passage of the electrode.

26. The device of claim 19, wherein the measurement signal processing apparatus comprises a further signal processing apparatus on a common circuit carrier or a common circuit carrier stack.

27. The device of claim 26, wherein the measurement signal processing apparatus is embodied to communicate at system level by the common circuit carrier.

28. The device of claim 19, wherein the measurement signal processing apparatus includes a BUS system for combining measurement signals and a connection for data output.
